(19) United States
(12) Patent Application Publication
(10) Pub. No.: US 2007/0069288 A1
(43) Pub. Date: Mar. 29, 2007

(54) Semiconductor device and method for manufacturing semiconductor device

(75) Inventor: Yasuhiro Takeda, Ogaki-shi (JP)

Correspondence Address: MCDERMOTT WILL & EMERY LLP, 600 13TH STREET, N.W., WASHINGTON, DC, 20005-3096, US

(73) Assignee: SANYO ELECTRIC CO., LTD.

(21) Appl. No.: 11/529,276

(22) Filed: Sep. 29, 2006

(30) Foreign Application Priority Data
Sep. 29, 2005 (JP) 2005-283535

(51) Int. Cl. H01L 21/8234

(52) U.S. Cl. 257/341; 438/197

(57) ABSTRACT

A semiconductor device for preventing a parasitic bipolar transistor from operating while reducing the ON resistance of a double-diffused MOS transistor. Boron having a relatively high solid solubility limit in silicon and indium having a relatively low solid solubility limit in silicon are diffused as p-type impurities into a body region. The concentration ratio of indium with respect to boron is higher in the vicinity of a source diffusion layer in the body region than in other portions. Thus, indium that does not solidify remains in the lattice of silicon. This reduces the lifetime of carriers in the body region and prevents the parasitic bipolar transistor from operating. The lateral junction abruptness at a pn junction between the body region and the source diffusion layer is improved, and the ON resistance of the DMOS transistor is reduced.

### CROSS-REFERENCE TO RELATED APPLICATIONS

This application is based upon and claims the benefit of priority from the prior Japanese Patent Application No. 2005-283535, filed on Sep. 29, 2005, the entire contents of which are incorporated herein by reference.

### BACKGROUND OF THE INVENTION

The present invention relates to a semiconductor device having a double-diffused metal oxide semiconductor (DMOS) transistor structure and to a method for manufacturing such a semiconductor device. More particularly, the present invention relates to an improvement in the structure and a manufacturing method for reducing influence from a parasitic bipolar transistor formed in the DMOS transistor structure.

In recent years, power semiconductor devices used in portable electronics devices or consumer electronics devices, more particularly, power semiconductor devices capable of withstand voltages of up to 100 V, are required to be further downsized. One example of such a semiconductor device is a double-diffused metal oxide semiconductor field effect transistor (DMOS FET), which is easily highly integrated.

FIG. 1 is a schematic cross-sectional view showing the structure of a DMOS transistor 100 included in a conventional semiconductor device. As shown in FIG. 1, a first conduction type epitaxial silicon layer 100b is formed on a second conduction type silicon substrate 100a, and a second conduction type impurity is diffused into the surface of the first conduction type epitaxial silicon layer 100b to form a body region 101. A first conduction type impurity having high concentration is diffused into the surface of the body region 101 to form a source diffusion layer 102. The source diffusion layer 102 is shallower than the body region 101, and is connected to a source electrode S. A gate electrode G is arranged above the body region 101 and beside the source diffusion layer 102 with a gate oxide 103 arranged in between. Further, a first conduction type impurity having high concentration is diffused into the surface of the first conduction type epitaxial silicon layer 100b to form a drain diffusion layer 105 beside the gate electrode G. The drain diffusion layer 105 is connected to a drain electrode D.

The DMOS transistor 100 forms a parasitic bipolar transistor in which the source diffusion layer 102 functions as an emitter E, the body region 101 functions as a base B, and the first conduction type epitaxial silicon layer 100b functions as a collector C. When the DMOS transistor 100 is operating, impact ionization may cause carriers to be generated in the body region 101. In this case, the potential of the body region 101, which should be clamped to the source potential, may change to generate a base current. This may cause the parasitic bipolar transistor to operate. As a result, unintended current may flow between the source electrode S and the drain electrode D thereby destabilizing the operation of the DMOS transistor 100.

Japanese Laid-Open Patent Publication No. 62-39069 and R&D Review (Vol.35, No.2, 2000.6, pp.3-10) of Toyota Central Labs., Inc. describe techniques for preventing such a parasitic bipolar transistor from operating. More specifically, the conventional techniques use lifetime killers, such as a gold diffusion layer and a lattice defect layer, formed in and near the body region 101 of the DMOS transistor 100.

The ON resistance of the DMOS transistor 100 is effectively reduced by miniaturizing elements. However, when the junction depth of the body region 101 and the source diffusion layer 102 is reduced to miniaturize elements, the base layer becomes thin. This increases the current gain of the parasitic bipolar transistor. When the junction depth of the body region 101 and the source diffusion layer 102 is reduced, the contact resistance between the source electrode S and the source diffusion layer 102 and the diffusion layer resistance of the body region 101 increase. This increases a parasitic resistance Rp formed between the base B (the body region 101) of the parasitic bipolar transistor and the source electrode S. As a result, carriers generated in the body region 101 cause the potential of the body region 101 to change over a long period of time. Further, when the junction depth of the body region 101 and the source diffusion layer 102 is reduced, a gold diffusion layer or a lattice defect layer described in the above publications may be difficult to form in the body region 101.

As a result, influence from the parasitic bipolar transistor may become significant so that the operation of the DMOS transistor 100 inevitably becomes unstable. It is difficult to satisfy both the need for preventing the parasitic bipolar transistor from operating and the need for reducing the ON resistance of the DMOS transistor.

### SUMMARY OF THE INVENTION

The present invention provides a semiconductor device that prevents a parasitic bipolar transistor from operating while reducing the ON resistance of a double-diffused transistor. The present invention also provides a manufacturing method for such a semiconductor device.

One aspect of the present invention is a semiconductor device provided with a double-diffused transistor including a semiconductor having a first type of conductivity, a body region formed in the semiconductor and having a second type of conductivity, and a source diffusion layer formed in the body region and having the first type of conductivity. The body region includes a first impurity having the second type of conductivity, and a second impurity having the second type of conductivity, a solid solubility limit and a diffusivity in the semiconductor that are lower than those of the first impurity, and a concentration ratio that is relatively high with respect to the first impurity in the body region.

A further aspect of the present invention is a method for forming a double-diffused transistor. The method includes implanting into a semiconductor having a first type of conductivity a first impurity having a second type of conductivity to form a body region, implanting into the body region an impurity having the first type of conductivity to form a source diffusion layer, and implanting into the body region a second impurity having the second type of conductivity and a solid solubility limit and a diffusivity in the semiconductor that are lower than those of the first impurity.

Other aspects and advantages of the present invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a schematic cross-sectional view of a DMOS transistor included in a conventional semiconductor device;

FIG. 2 is a schematic cross-sectional view of a DMOS transistor included in a semiconductor device according to a preferred embodiment of the present invention;

FIG. 3-1 is a schematic cross-sectional view showing a manufacturing method for the DMOS transistor of FIG. 2;

FIG. 3-2 is a schematic cross-sectional view showing the manufacturing method for the DMOS transistor of FIG. 2;

FIG. 3-3 is a schematic cross-sectional view showing the manufacturing method for the DMOS transistor of FIG. 2;

FIG. 3-4 is a schematic cross-sectional view showing the manufacturing method for the DMOS transistor of FIG. 2;

FIG. 3-5 is a schematic cross-sectional view showing the manufacturing method for the DMOS transistor of FIG. 2;

FIG. 3-6 is a schematic cross-sectional view showing the manufacturing method for the DMOS transistor of FIG. 2;

FIG. 3-7 is a schematic cross-sectional view showing the manufacturing method for the DMOS transistor of FIG. 2;

FIG. 3-8 is a schematic cross-sectional view showing the manufacturing method for the DMOS transistor of FIG. 2;

FIG. 3-9 is a schematic cross-sectional view showing the manufacturing method for the DMOS transistor of FIG. 2;

FIG. 3-10 is a schematic cross-sectional view showing the manufacturing method for the DMOS transistor of FIG. 2;

FIG. 4 is a graph showing the carrier concentration distribution of impurities;

FIG. 5 is a graph showing the relationship between the lateral junction abruptness and the parasitic resistance at a pn junction between a source diffusion layer and a body region of the DMOS transistor;

FIG. 6 is a schematic cross-sectional view showing an indium diffusion layer according to another embodiment of the present invention;

FIG. 7 is a schematic cross-sectional view of a DMOS transistor included in a semiconductor device according to a further embodiment of the present invention;

FIG. 8 is a schematic cross-sectional view of a vertical DMOS transistor according to another embodiment of the present invention; and

FIG. 9 is a schematic cross-sectional view showing an insulated gate bipolar transistor (IGBT) included in a semiconductor device according to a further embodiment of the present invention.

### DETAILED DESCRIPTION OF THE PREFERRED EMBODIMENTS

In the drawings, like numerals are used for like elements throughout.

A semiconductor device according to a preferred embodiment of the present invention will now be described with reference to FIGS. 2 to 5.

FIG. 2 is a schematic cross-sectional view showing the structure of a DMOS transistor 200 included in the semiconductor device of the preferred embodiment. As shown in FIG. 2, the DMOS transistor 200 has a substrate formed by a p-type silicon substrate 1 and an n-type epitaxial silicon layer 2. The n-type epitaxial silicon layer 2 is formed on the p-type silicon substrate 1 and functions as a drift layer for the DMOS transistor 200. P-type impurities are diffused into the surface of the n-type epitaxial silicon layer 2 to form a body region 10. An n-type impurity (in this case, arsenic As) having a relatively high concentration is diffused into the body region 10 to form a source diffusion layer 12a. The source diffusion layer 12a is formed to be shallower than the body region 10. A gate electrode 7 is arranged above the body region 10, with a gate oxide film 5 arranged in between, at a position where the source diffusion layer 12a is not formed. An oxide film 4 is formed below the gate electrode 7 through local oxidation of silicon (LOCOS). An n-type impurity (in this case, arsenic) having a relatively high concentration is diffused into the surface of the n-type epitaxial silicon layer 2 to form a drain diffusion layer 12b at a position opposite to the source diffusion layer 12a with respect to the oxide film 4.

In the semiconductor device of the present embodiment, boron B, which has a relatively high solid solubility limit and a relatively high diffusivity in the silicon forming the substrate, and indium In, which has a relatively low solid solubility limit and a relatively low diffusivity in silicon, are diffused into the body region 10 as p-type impurities. In the body region 10, indium In is diffused into the vicinity of the source diffusion layer 12a. The concentration ratio of indium In to boron B is higher in the vicinity of the source diffusion layer 12a than in other portions of the body region 10. Further, the peak concentration of indium In is higher than its solid solubility limit in silicon. Thus, the lifetime of carriers in the body region 10 is reduced, and the parasitic bipolar transistor is prevented from operating. Further, the lateral junction abruptness at the junction between the body region 10 and the source diffusion layer 12a is improved. As a result, the ON resistance of the DMOS transistor 200 is reduced.

A method for manufacturing the semiconductor device including the DMOS transistor 200 shown in FIG. 2 will now be described.

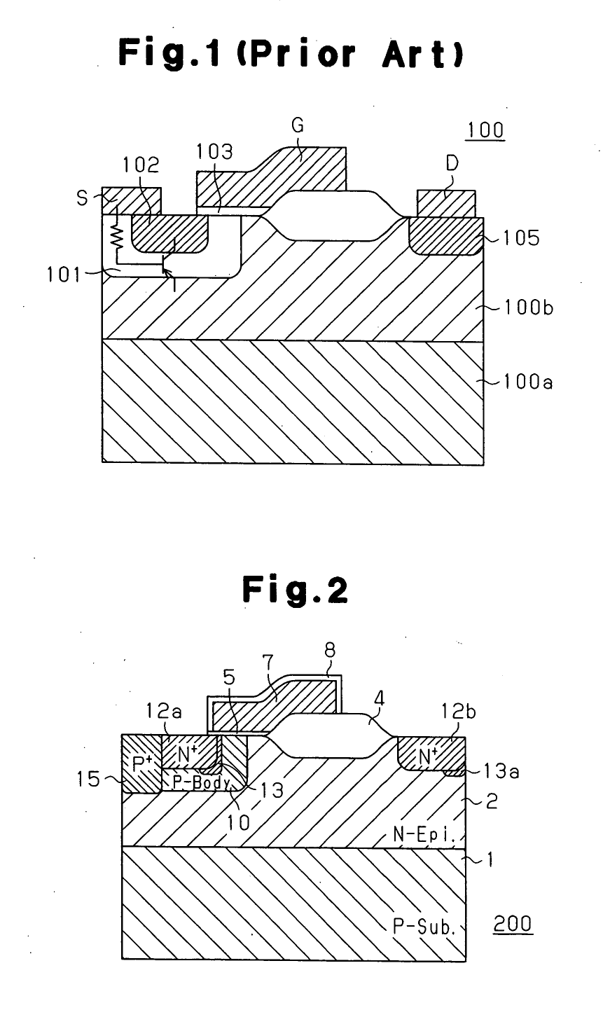

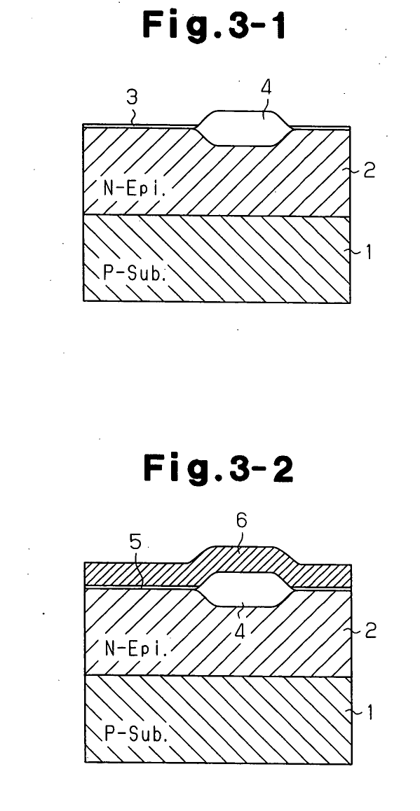

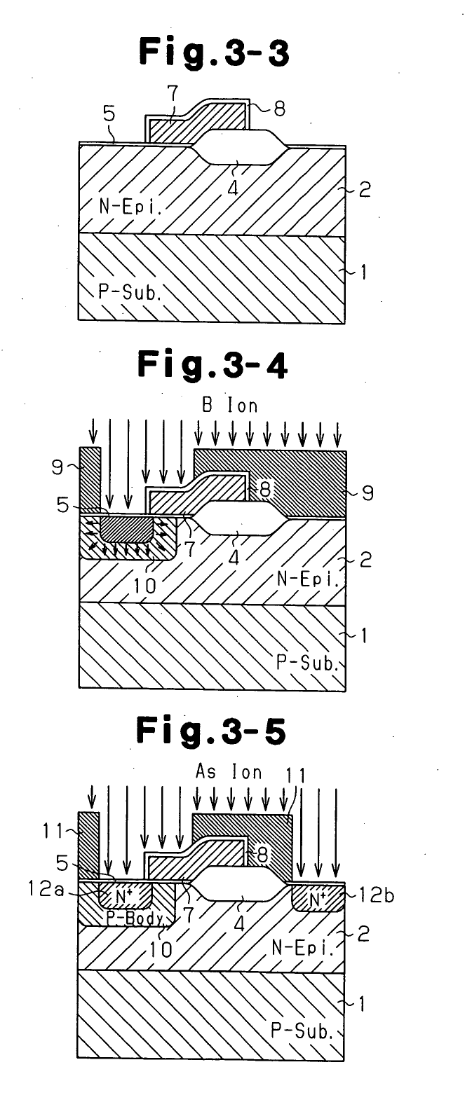

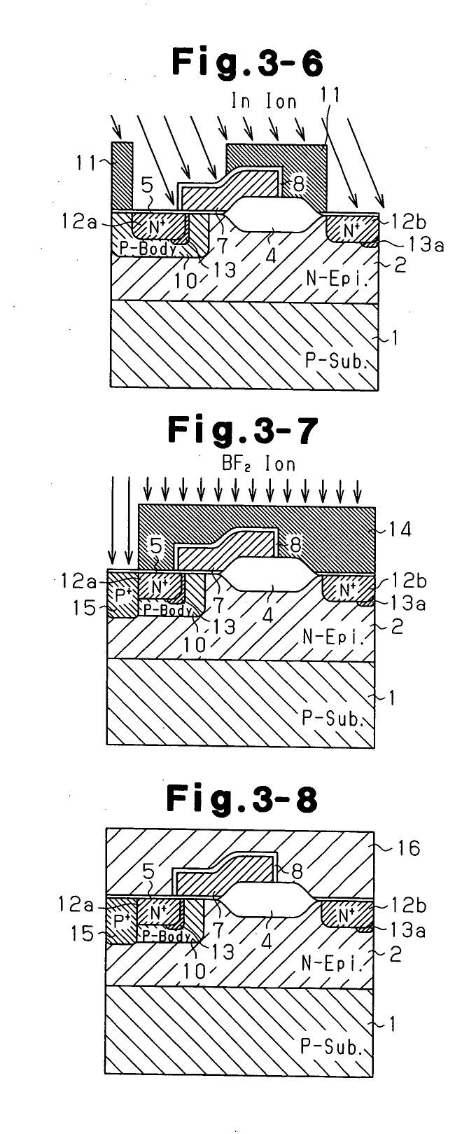

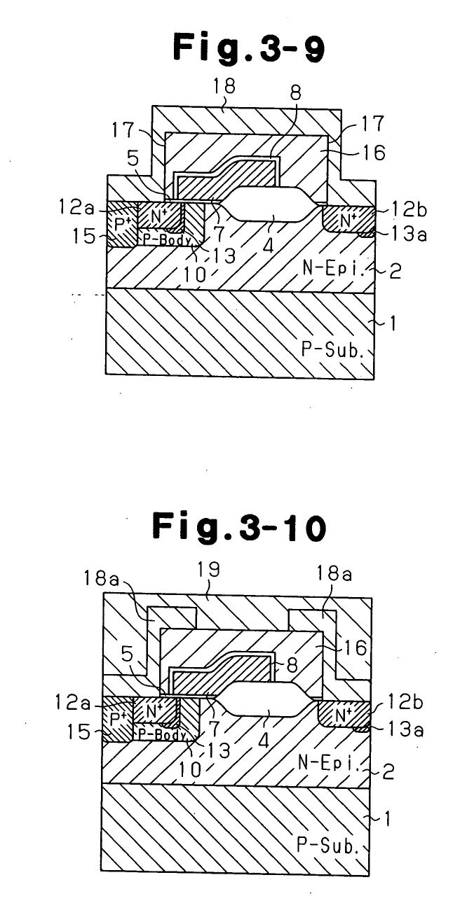

Referring to FIG. 3-1, an n-type epitaxial silicon layer 2 having a specific resistance of about 1 to 2 Ω·cm is formed on a p-type silicon substrate 1 to have a film thickness of about 3 μm. Next, LOCOS and pn junction isolation is carried out to perform element isolation. Further, a thick oxide film 4, which reduces the electric field formed between the gate and the drain of the DMOS transistor 200 or offsets a drain diffusion layer 12b, is formed in parallel with the element isolation performed through LOCOS.

Next, a sacrificial oxide film 3 having a film thickness of about 200 Å is formed on the upper surface of the n-type epitaxial silicon layer 2. Ion implantation into the p-type silicon substrate 1 and the n-type epitaxial silicon layer 2 through the sacrificial oxide film 3 is then performed to adjust the threshold voltage or the withstand voltage.

Afterward, the sacrificial oxide film 3 is removed. Referring to FIG. 3-2, a gate oxide film 5 having a film thickness of about 200 Å is formed on the n-type epitaxial silicon layer 2 in a mixture of oxygen gas and hydrogen gas. Then, a polysilicon film 6 having a thickness of about 2000 Å is formed by depositing polysilicon on the upper surface of the gate oxide film 5 through, for example, LP-CVD (low pressure chemical vapor deposition). Heat treatment using, for example, phosphorous oxychloride (POCl3), is then performed to dope the polysilicon film 6 with phosphor P.

After the phosphor glass generated by the doping of phosphor P is removed, referring to FIG. 3-3, unnecessary portions of the polysilicon film 6 is removed through photolithography to form a gate electrode 7. A re-oxidized layer 8 having a film thickness of about 100 Å is formed on the surface of the gate electrode 7 in an oxygen atmosphere under a temperature of 900° C.

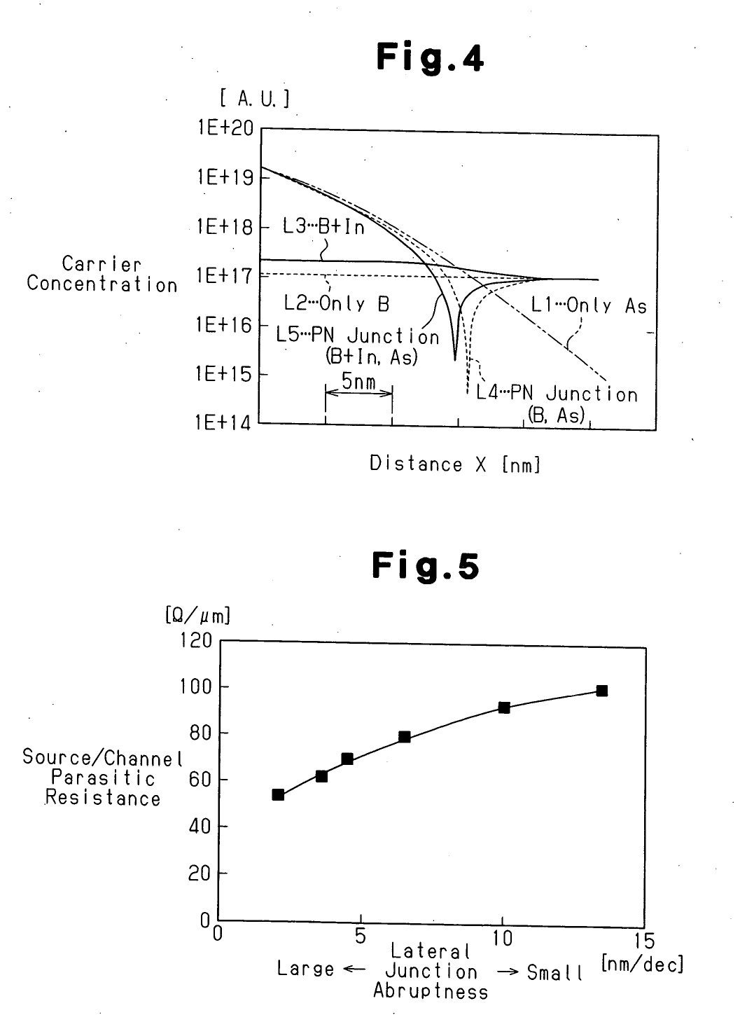

Next, referring to FIG. 3-4, boron B (a first impurity having a second type of conductivity) is diffused into the surface of the n-type epitaxial silicon layer 2 to form a body region 10. The diffusion of boron B is performed using a mask 9 having an opening in correspondence with the source region. In detail, born B is ion-implanted with an energy of about 40 KeV and at a density of about 10¹⁴ ions per square centimeter. Afterwards, heat treatment is performed for about 1 hour under a temperature of about 900° C. In this way, the body region 10 is formed through heat diffusion.

After the body region 10 is formed, referring to FIG. 3-5, arsenic As (an impurity having a first type of conductivity) is ion-implanted using a mask 11 having openings in correspondence with areas in which the source diffusion layer 12a and the drain diffusion layer 12b are to be formed. The arsenic As implantation is performed with an energy of about 60 KeV and at a density of about 2*10¹⁵ ions per square centimeter. The source diffusion layer 12a and the drain diffusion layer 12b are formed in this manner.

Further, referring to FIG. 3-6, indium In (a second impurity having a second type of conductivity) is ion-implanted using the same mask 11. The In implantation is performed with an energy of about 160 KeV and at a density of about 1.5*10¹³ ions per square centimeter. The In implantation is performed at an inclination angle of 30 to 60°. As a result, indium In is implanted locally only at a source end of the source diffusion layer 12a. More specifically, indium In is implanted locally in an area on the junction between the body region 10 and the source diffusion layer 12a that faces the drain diffusion layer 12b (in the vicinity of the right side of the source diffusion layer 12a in FIG. 3-6). The indium diffusion layer 13 is formed in this manner.

During the indium In implantation, indium In is also implanted in the drain diffusion layer 12b. If indium In is implanted near a drain end of the drain diffusion layer 12b, which is located in a main current passage between the source and the drain of the DMOS transistor 200, this would increase the ON resistance of the DMOS transistor 200. To prevent this, the implanting direction of indium In is inclined as described above to limit the formation area for an indium diffusion layer 13a. More specifically, indium In is implanted at a predetermined inclination angle in a manner that an area in the junction between the silicon layer 2 and the drain diffusion layer 12b that faces the source diffusion layer 12a vicinity of left side of the indium diffusion layer 13a in FIG. 3-6) is hidden by the mask 11. This prevents indium In from being implanted in the vicinity of the drain end of the drain diffusion layer 12b.

The peak concentration of indium In diffused into each of the indium diffusion layers 13 and 13a is about 10¹⁸ ions per square centimeter. The solid solubility limit of indium In in silicon Si is about 2*10¹⁷ ions per square centimeter in an equilibrium state and is about 7*10¹⁷ ions per square centimeter even in a non-equilibrium state. Thus, some of the implanted indium In does not solidify and remains in the lattice of silicon.

After indium In is implanted, referring to FIG. 3-7, boron fluoride BF2 is ion-implanted using a mask 14 having an opening in correspondence with a contact portion between a source electrode (not shown) and the body region 10. As a result, a p+ diffusion layer 15 is formed in the surface of the n-type epitaxial silicon layer 2 at a position corresponding to the contact portion between the source electrode and the body region 10. The BF2 implantation is performed with an energy of about 60 KeV and at a density of about 3*10¹⁵ ions per square centimeter. Afterwards, heat treatment is performed for about 10 seconds under a temperature of about 1000° C. This activates arsenic As implanted in each of the formation areas of the source diffusion layer 12a and the drain diffusion layer 12b and indium In implanted in each of the formation areas of the indium diffusion layers 13 and 13a.

Afterwards, referring to FIG. 3-8, an interlayer insulation film 16 is formed to cover the entire surface of the substrate by performing, for example, LP-CVD using Si(OC₂H₅)₄, or tetraethyl orthosilicate (TEOS). Next, referring to FIG. 3-9, contact holes 17 are formed in the interlayer insulation film 16 through photolithography. Then, a metal film 18 is formed by depositing aluminum Al or the like on the silicon substrate through sputtering. Further, referring to FIG. 3-10, wiring 18a is formed by removing unnecessary portions of the metal film 18 by performing lithography. A passivation layer 19 is formed on the wiring 18a. This completes the manufacture of the DMOS transistor 200.

In the DMOS transistor 200 of the semiconductor device of the preferred embodiment manufactured through the above method, the indium diffusion layer 13 is locally formed at the source end of the source diffusion layer 12a. The solid solubility limit and the diffusivity of indium In, which is diffused into the indium diffusion layer 13, in the silicon substrate (silicon) are lower than those of boron B. The indium diffusion layer 13 contains indium In that does not solidify and remains between the crystals of silicon. Such indium In that does not solidify functions as a lifetime killer that reduces the lifetime of carriers. When the DMOS transistor 200 is operating, carriers generated by impact ionization or the like are prevented from changing the potential at the body region 10. As a result, the indium diffusion layer 13 prevents the parasitic bipolar transistor from operating and improves the operation stability of the DMOS transistor 200.

Further, the indium diffusion layer 13 improves the lateral junction abruptness of impurities at the interface between the source diffusion layer 12a and the body region 10. The lateral junction abruptness of impurities indicates the steepness of the gradient of the curve representing the concentration of impurities in the lateral direction of the silicon substrate, or in the direction in which the substrate surface extends.

FIG. 4 shows the carrier concentration distribution of impurities in four silicon substrates having different diffused impurities. In FIG. 4, the vertical axis indicates the carrier concentration of impurities [A.U.], and the horizontal axis indicates the distance (nm) in the lateral direction from a specific reference position, which is spaced from the diffusion center of impurities by a predetermined distance.

Only arsenic As is diffused into the substrate represented by curve L1. Only boron B is diffused into the substrate represented by curve L2. Boron B and indium In are diffused into the substrate represented by curve L3. Arsenic As and boron B are diffused to form a pn junction in the substrate represented by curve L4. The pn junction corresponds to a junction of the body region 10 and the source diffusion layer 12a when the indium diffusion layer 13 is not formed. In addition to arsenic As and boron B, indium In is diffused into the substrate represented by curve L5. Further, in this substrate, a pn junction is formed by arsenic As, boron B, and indium In. The pn junction corresponds to a junction between the body region 10 and the source diffusion layer 12a in a portion at which the indium diffusion layer 13 is formed in the present embodiment.

As indicated by curve L2 in FIG. 4, when boron B, which has a relatively high diffusivity with respect to the silicon substrate, is diffused, the carrier concentration shows almost no decrease within the range shown in FIG. 4 as even if the distance described above increases. When indium In is diffused into addition to boron B, as indicated by curve L3, the carrier concentration decreases at a gradient greater than that when only boron B is diffused. This is because the diffusivity of indium In with respect to the silicon substrate is relatively low.

As apparent from the comparison between curve L4 and curve L5, the carrier concentration of impurities in the lateral direction at the pn junction formed by arsenic As, born B, and indium In decreases at a gradient steeper than that at the pn junction formed only by arsenic As and boron B.

FIG. 5 shows the relationship between the lateral junction abruptness and the source-channel parasitic resistance (Ω/μm) per unit transistor width at the junction between the body region 10 and the source diffusion layer 12a. In FIG. 5, the horizontal axis indicates the distance (nm/dec) in the lateral direction when the carrier concentration decreases by one digit at the pn junction. A smaller value of the distance indicates a higher lateral junction abruptness at the pn junction. In FIG. 5, the vertical axis indicates the parasitic capacitance per micrometer transistor width (Ω/μm). As shown in FIG. 5, as the lateral junction abruptness increases, the source-channel channel parasitic resistance decreases. This consequently reduces the ON resistance of the DMOS transistor 200.

The semiconductor device and the manufacturing method for the semiconductor device of the first embodiment have the advantages described below.

(1) The indium diffusion layer 13 is formed locally in the vicinity of the source diffusion layer 12a in the body region 10. Thus, the lifetime of carriers in the body region 10 is reduced, and the parasitic bipolar transistor is prevented from operating. Further, the lateral junction abruptness at the junction between the body region 10 and the source diffusion layer 12a is improved. As a result, the ON resistance of the DMOS transistor 200 is reduced.

(2) The indium diffusion layer 13 is formed using the same mask 11 that is also used to form the source diffusion layer 12a. This eliminates the need for additional processes of forming a mask and removing the mask, and enables the DMOC transistor 200 to be easily manufactured.

(3) The source diffusion layer 12a and the drain diffusion layer 12b are formed simultaneously by performing a single implantation of arsenic As. This simplifies the manufacturing processes.

(4) Indium In is implanted at a predetermined inclination angle in a manner that the drain distal end of the drain diffusion layer 12b is hidden behind the mask 11. This prevents indium In from being implanted in the vicinity of the drain distal end of the drain diffusion layer 12b that is on the main current passage when the DMOS transistor 200 is operating. Thus, the ON resistance of the DMOS transistor 200 is prevented from increasing unnecessarily.

It should be apparent to those skilled in the art that the present invention may be embodied in many other specific forms without departing from the spirit or scope of the invention. Particularly, it should be understood that the present invention may be embodied in the following forms.

In the preferred embodiment, a mask for preventing indium In from being implanted in the vicinity of the source end of the source diffusion layer 12a and the drain end of the drain diffusion layer 12b may be used when indium In is implanted. More specifically, a mask, which differs from the mask used when arsenic As is implanted, may be used when indium In is implanted at a right angle into the substrate.

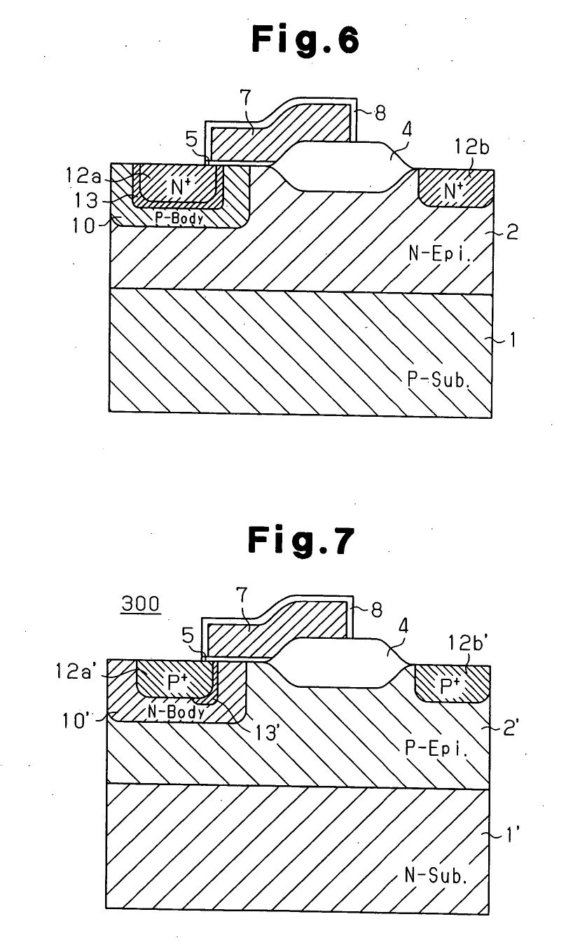

In the above embodiment, the indium diffusion layer 13 may be formed to cover the entire junction between the body region 10 and the source diffusion layer 12a as shown in FIG. 6. It is only required that an indium diffusion layer with a relatively high concentration be formed in the vicinity of the source diffusion layer 12a in the body region 10. In this case, the ON resistance of the DMOS transistor 200 is reduced while the parasitic bipolar transistor is prevented from operating. When indium In is implanted at a right angle into the substrate, the indium diffusion layer 13 is formed to cover the entire junction between the body region 10 and the source diffusion layer 12a as shown in FIG. 6.

In the above embodiment, the first type of conductivity may be p-type and the second type of conductivity may be n-type in a DMOS transistor 300 shown in FIG. 7. In the semiconductor device shown in FIG. 7, a p-type epitaxial silicon layer 2′ is formed on the upper surface of an n-type silicon substrate 1′, and the DMOS transistor 300 is formed on the layer 2′. Boron B, which is a p-type impurity, is diffused into a source diffusion layer 12a′ and a drain diffusion layer 12b′. Phosphor P, which is an n-type impurity, is diffused into a body region 10′. Antimony Sb, which is an n-type impurity, is diffused into the vicinity of the source diffusion layer 12a′ to locally form an antimony diffusion layer 13′. The solid solubility limit and the diffusivity of antimony Sb in silicon are lower than those of phosphor P. The DMOS transistor 300 formed in this manner has the same advantages as the preferred embodiment.

The two impurities forming the body region 10 should not be limited to boron B and indium In or should phosphor P and antimony Sb. Other combinations of impurities having a suitable solid solubility limit and diffusivity may be used to form the body region 10.

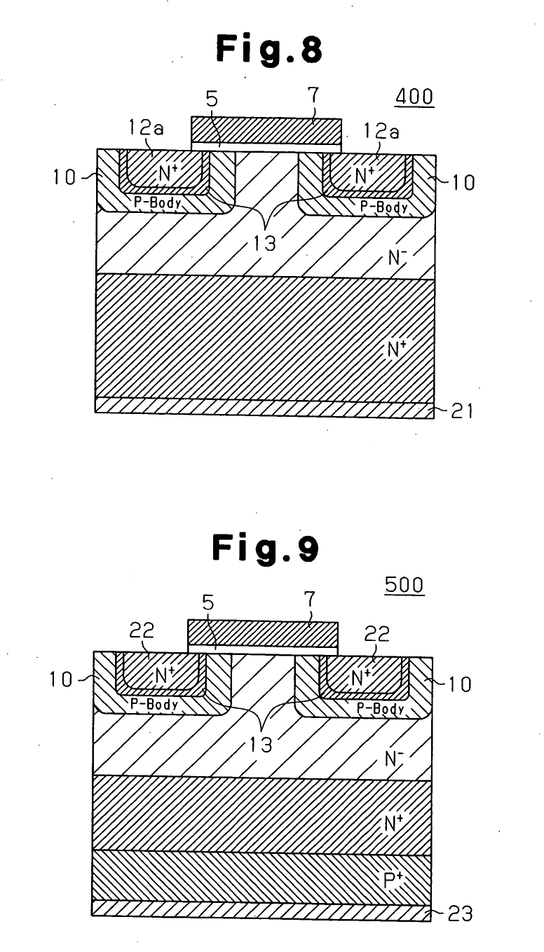

The present invention should not be limited to the semiconductor device including the DMOS transistor in which both the source electrode and the drain electrode are arranged on the substrate surface (horizontal DMOS transistor). For example, as shown in FIG. 8, the present invention is applicable to a DMOS transistor 400 in which current flows in the vertical direction to the substrate when the transistor is operating (vertical DMOS transistor). In the DMOS transistor 400, a source diffusion layer 12a is formed in the upper surface of the substrate and a drain electrode 21 is formed on the lower surface of the substrate.

As shown in FIG. 9, the present invention is also applicable to an insulated gate bipolar transistor (IGBT) 500, which is a device combining a double-diffused MOS transistor and a bipolar transistor. In the IGBT 500, a collector electrode 23 is formed on the lower surface of the substrate. A base region, in which an emitter diffusion layer 22 corresponding to the source diffusion layer 12a of the DMOS transistor 200 is formed (a body region 10 in the figure), is formed by two impurities that differ in their solid solubility limit and diffusivity. One of the impurities having a lower solid solubility limit and a lower diffusivity is formed locally in the vicinity of the emitter diffusion layer 22 with a relatively high impurity concentration ratio. The IGBT 500 formed in this manner also has the same advantages as the advantages described in the above embodiment.

The present examples and embodiments are to be considered as illustrative and not restrictive, and the invention is not to be limited to the details given herein, but may be modified within the scope and equivalence of the appended claims.

What is claimed is:

1. A semiconductor device comprising:
a double-diffused transistor including a semiconductor having a first type of conductivity, a body region formed in the semiconductor and having a second type of conductivity, and a source diffusion layer formed in the body region and having the first type of conductivity;
the body region including:
a first impurity having the second type of conductivity; and
a second impurity having the second type of conductivity, a solid solubility limit and a diffusivity in the semiconductor that are lower than those of the first impurity, and a concentration ratio that is relatively high with respect to the first impurity in the body region.

2. The semiconductor device according to claim 1, wherein the double-diffused transistor is a double-diffused metal oxide semiconductor transistor.

3. The semiconductor device according to claim 1, wherein concentration of the second impurity in a vicinity of the source diffusion layer is higher than the solid solubility limit of the second impurity in the semiconductor.

4. The semiconductor device according to claim 1, wherein the first impurity is boron and the second impurity is indium.

5. The semiconductor device according to claim 1, wherein the first impurity is phosphor and the second impurity is antimony.

6. A method for forming a double-diffused transistor, the method comprising:
implanting into a semiconductor having a first type of conductivity a first impurity having a second type of conductivity to form a body region;
implanting into the body region an impurity having the first type of conductivity to form a source diffusion layer; and
implanting into the body region a second impurity having the second type of conductivity and a solid solubility limit and a diffusivity in the semiconductor that are lower than those of the first impurity.

7. The method according to claim 6, wherein:
said implanting into the body region an impurity includes implanting the impurity having the first type of conductivity using a mask; and
said implanting into the body region a second impurity includes implanting the second impurity with the mask.

8. The method according to claim 6, wherein the double-diffused transistor is a double-diffused metal oxide semiconductor transistor.

9. The method according to claim 6, wherein said implanting into the body region a second impurity includes implanting the second impurity so that a concentration of the second impurity is higher than the solid solubility limit of the second impurity in the semiconductor.

10. The method according to claim 7, wherein:
the double-diffused transistor further includes a drain diffusion layer;
said implanting into the body region an impurity includes implanting the impurity having the first type of conductivity to form the drain diffusion layer simultaneously with the source diffusion layer; and
said implanting into the body region a second impurity includes implanting the second impurity at a predetermined inclination angle with respect to a surface of the semiconductor so that a drain end of the drain diffusion layer facing toward the source diffusion layer is hidden by the mask.

11. The method according to claim 6, wherein:
said implanting into a semiconductor includes implanting boron as the first impurity; and
said implanting into the body region a second impurity includes implanting indium as the second impurity.

12. The method according to claim 6, wherein:
said implanting into a semiconductor includes implanting phosphor as the first impurity; and
said implanting into the body region a second impurity includes implanting antimony as the second impurity.
